(19) United States
(12) Patent Application Publication
(10) Pub. No.: US 2026/0293719 A1
(43) Pub. Date: Sep. 24, 2026

(54) DECOUPLING OF CRAM FROM FPGA FABRIC USING BACKSIDE POWER RAIL

(71) Applicant: XILINX, INC., San Jose, CA (US)

(72) Inventors: Nui CHONG, San Jose, CA (US); Matthew H. KLEIN, Redwood City, CA (US); Shidong ZHOU, Milpitas, CA (US); Santosh YACHARENI, Hyderabad (IN)

(21) Appl. No.: 19/083,772

(22) Filed: Mar. 19, 2025

(51) Int. Cl. H01L 23/538; H01L 23/00; H01L 25/18; H10B 80/00

(52) U.S. Cl. CPC H10W 70/65; H10B 80/00; H10W 70/611; H10W 70/635; H10W 90/00; H10W 90/722; H10W 90/791

(57) ABSTRACT

The examples describe a chip package including a memory array including configuration memory and associated support circuits for reading, writing, and repair and a field-programmable gate array (FPGA) fabric including configurable logic elements (CLEs) and interconnect (INT) multiplexers, where the FPGA fabric is stacked onto the memory array. The FPGA fabric includes a backside power rail (BPR). The BPR is configured to supply power and ground to both the memory array and the FPGA fabric using back-side vias (BSVs) and back-side metal rails. The BPR is configured to supply logic states (Q/QB) to both the memory array and the FPGA fabric using BSVs. Electrical connection between the memory array and the FPGA fabric is established using hybrid bonding.

### TECHNICAL FIELD

Examples of the present disclosure generally relate to integrated circuits, and, in particular, to decoupling configuration random access memory (CRAM) from field-programmable gate array (FPGA) fabric using backside power rail technology.

### BACKGROUND

Field-programmable gate arrays (FPGAs) are versatile semiconductor devices that rely on configuration random access memory (CRAM) to store and control their programmable logic and interconnects. Traditionally, CRAM is embedded directly within the FPGA fabric, where individual CRAM bit cells are tightly coupled to the programmable elements they configure. These bit cells provide logic state (Q/QB) outputs that directly program configurable logic elements (CLEs), such as look-up tables (LUTs), and control the state of interconnect multiplexers (INT muxes) within the routing fabric. This architecture ensures fast configuration and tight integration, enabling the high performance and reconfigurability of FPGAs.

However, the reliance on non-repairable static random access memory (SRAM)-based CRAM bit cells introduces challenges, including susceptibility to soft errors and yield loss due to manufacturing defects. Additionally, the embedded nature of CRAM within the FPGA fabric limits the scalability and flexibility of configuration storage, constraining the ability to adopt alternative memory technologies or redundancy techniques. These limitations highlight the need for innovative approaches to improve the reliability, scalability, and repairability of CRAM while maintaining the FPGA's programmability and performance.

### SUMMARY

One example described herein is a chip package including a field-programmable gate array (FPGA) fabric chiplet including a backside power rail (BPR), where the FPGA fabric chiplet excludes memory elements and a memory chiplet electrically connected to the FPGA fabric chiplet.

One example described herein is a chip package including a memory array including configuration memory and associated support circuits for reading, writing, and repair and a field-programmable gate array (FPGA) fabric including configurable logic elements (CLEs) and interconnect (INT) multiplexers, where the FPGA fabric is stacked onto the memory array.

One example described herein is a method including forming a backside power rail (BPR) in a field-programmable gate array (FPGA) fabric chiplet excluding memory elements and electrically connecting a memory chiplet to the FPGA fabric chiplet.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a cross-sectional view of a field-programmable gate array (FPGA) fabric chiplet including a backside power rail (BPR) and a configurable random access memory (CRAM) chiplet connected to the FPGA fabric chiplet with BPR using microbumps, according to an example.

FIG. 2 illustrates a cross-sectional view of a FPGA fabric chiplet including a BPR and a CRAM chiplet connected to the FPGA fabric chiplet with BPR using hybrid bonding, according to an example.

FIG. 3 illustrates a process for bonding a first wafer including FPGA fabric chiplets to a second wafer including CRAM chiplets, according to an example.

FIG. 4 illustrates a face-to-face wafer-to-wafer interface, according to an example.

FIG. 5 illustrates a method for decoupling the FPGA fabric chiplet with BPR from the CRAM chiplet, according to an example.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the examples herein or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Field-programmable gate arrays (FPGAs) are hardware devices that can be configured post-manufacturing to implement a wide range of digital logic functions. This programmability is enabled by configuration random access memory (CRAM), a specialized type of volatile memory embedded within the FPGA fabric. CRAM is fundamental to the operation of FPGAs, storing the configuration data that dictates the behavior of programmable logic and interconnect resources. Through its integration within the FPGA, CRAM enables rapid reconfiguration and adaptability, making FPGAs ideal for diverse applications like artificial intelligence (AI) acceleration and custom hardware designs.

CRAM bit cells serve as the core memory units responsible for storing the configuration bits. These bit cells are connected directly to key programmable elements within the FPGA fabric. Each CRAM cell includes a pair of complementary nodes, Q and QB, which represent the stored logic state. These logic state (Q/QB) nodes directly control the functionality of FPGA components, including interconnect multiplexers (INT muxes) and configurable logic elements (CLEs).

The interconnect (INT) network in FPGAs includes routing tracks and programmable switches that allow signals to flow between logic blocks. CRAM bit cells, through their Q/QB nodes, directly program these interconnect multiplexers by enabling or disabling specific routing paths. This fine-grained control ensures that signals can traverse the FPGA fabric according to the desired configuration. The ability to dynamically reprogram these paths is one of the defining features of FPGAs, enabling them to adapt to new circuit designs without the need for hardware modifications.

CLEs are the fundamental building blocks of FPGAs, providing the computational resources needed to implement logic functions. Within each CLE, look-up tables (LUTs) are configured to represent specific truth tables or functions. CRAM bit cells directly program these LUTs by driving the Q nodes to store the corresponding logic values. This integration of CRAM with CLEs allows for the rapid configuration of complex logic functions, enabling FPGAs to achieve high performance and versatility in executing digital designs.

The embedding of CRAM within the FPGA fabric is a feature that enhances both performance and scalability. By situating CRAM bit cells adjacent to the components they control, such as INT muxes and CLEs, the FPGA minimizes latency and routing overhead. This integration ensures that configuration changes propagate efficiently, enabling rapid reconfiguration and reducing power consumption. The dense embedding of CRAM also allows FPGAs to support increasingly complex designs, as the number of programmable elements scales with the size of the CRAM.

In traditional FPGA designs, the CRAM stores the programming data that configures the logic resources (such as LUTs, flip-flops, and muxes) and interconnects within the FPGA. However, one limitation in conventional FPGA architecture is the lack of efficient repair mechanisms for faults in the CRAM, especially single-bit failures. These faults can have a substantial impact on the FPGA's functionality, leading to a situation where a single faulty bit in the CRAM may result in incorrect programming of the FPGA fabric, thus causing failures in logic operations and rendering the FPGA unusable.

The challenge with repairing CRAM failures is that, in traditional FPGA architectures, the configuration memory is tightly coupled with the FPGA fabric, often integrated within the same chip. This close coupling means that any failure within the CRAM can affect the entire FPGA system. Further, when a single-bit failure occurs in the CRAM, there are no straightforward mechanisms to isolate and repair that bit independently without affecting the entire configuration. This can result in a yield failure for the entire FPGA, even if the issue is isolated to just one or a few configuration bits.

Since the CRAM is responsible for configuring not only the logic elements but also the interconnects that connect them, a faulty bit in the configuration memory can result in incorrect routing or operation of the logic elements. For example, a single bit failure may cause a connection to be wrongly established or prevent the configuration of a logic element altogether, leading to system malfunction. The lack of an efficient repair mechanism for these single-bit failures limits the reliability and yield of FPGA manufacturing processes.

In view of such challenges, the examples present a method and system for decoupling the CRAM from the FPGA fabric, allowing the configuration memory to be handled in a separate chiplet. This separation opens up opportunities for more advanced memory repair schemes, such as error correction codes (ECC), redundancy, or dynamic reconfiguration, to be implemented specifically within the CRAM chiplet. When the CRAM is isolated from the FPGA fabric, it becomes possible to introduce targeted repairs for specific bits or even entire sections of the CRAM without impacting the overall FPGA fabric's performance or functionality.

With a separate CRAM chiplet, the FPGA architecture can use more advanced memory technologies such as DRAM or non-volatile memories, which often come with built-in error correction capabilities. Other combinational logics such as flip-flops or state machines can also be used as memories for features such as on-the-fly programming and correction. By isolating the CRAM, these memory technologies can be used in a more flexible and scalable manner, allowing for better fault tolerance. For instance, if a single-bit failure occurs in the configuration memory, it can be detected and corrected without disrupting the FPGA's functionality, thus significantly improving the reliability and yield of the FPGA.

Additionally, a dedicated repair scheme within the CRAM chiplet, such as using spare memory cells or implementing on-the-fly configuration corrections, can ensure that faults in the CRAM do not propagate and affect the logic or interconnect layers of the FPGA. This repair mechanism allows for a much more granular approach to fault management, which is difficult to achieve in traditional FPGA designs where the CRAM and fabric are coupled. By providing a way to repair or bypass faulty bits, the example approach not only increases the robustness of the FPGA but also enhances its overall reliability and long-term performance.

As such, the decoupling of CRAM from the FPGA fabric offers several significant benefits, including reduced design constraints, improved memory repair schemes, better yield management, enhanced fault isolation, and greater scalability. By allowing the CRAM to be handled independently as a separate chiplet, these advancements pave the way for more reliable, flexible, and scalable FPGA designs. This separation not only improves the efficiency and performance of the FPGA but also enables easier adoption of new memory technologies and faster repair of faults, ultimately leading to better manufacturing yields and more reliable end-user products.

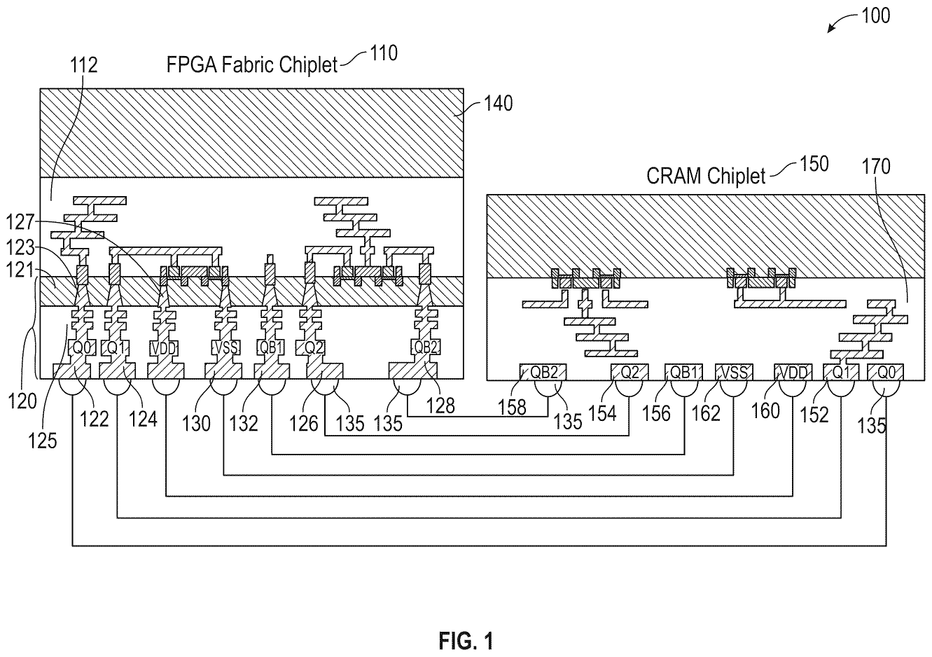

FIG. 1 illustrates a cross-sectional view of a field-programmable gate array (FPGA) fabric chiplet including a backside power rail (BPR) and a configurable random access memory (CRAM) chiplet connected to the FPGA fabric chiplet with BPR using microbumps, according to an example.

The structure 100 includes a FPGA fabric chiplet 110 and a CRAM chiplet 150. The structure 100 can be referred to as a chip-on-wafer-on-substrate (CoWoS) structure, a chip package, a semiconductor package assembly, or a semiconductor chip device. In one example, the FPGA fabric chiplet 110 connects or couples to the CRAM chiplet 150 using microbumps 135.

The FPGA fabric chiplet 110 includes programmable logic blocks, interconnects, and input/output (I/O) blocks. The FPGA fabric chiplet 110 is a network of programmable routing resources that enable connections between logic blocks and I/O pins. The FPGA fabric chiplet 110 may include switch matrices that enable the programmable connections between wires in the FPGA, routing tracks, which are wires that span different lengths and directions, allowing signals to travel across the FPGA, and programmable switches that are controlled by CRAM cells, and determine which connections are active within the FPGA fabric chiplet 110.

The CRAM chiplet 150 includes CRAM, which is a type of memory used to store configuration data that defines the functionality of the programmable logic and interconnects. CRAM is volatile, meaning it loses its content when power is turned off. Upon powering on, the FPGA needs to be configured (usually via an external memory or flash device) to load the necessary bitstream into the CRAM. CRAM cells are small memory units that hold the binary configuration data for an FPGA. Each CRAM cell controls the state of programmable elements, such as logic blocks (e.g., look-up tables (LUTs)), routing switches, and interconnects. The size of the CRAM determines the flexibility and complexity of the FPGA design.

The traditional integration of CRAM within FPGA fabric couples the configuration memory to the programmable elements. While this design enables compactness and efficiency, it relies heavily on non-repairable SRAM bit cells. These bit cells are small, fast, and consume low power but are vulnerable to defects during manufacturing and susceptible to soft errors caused by radiation. To address these limitations, decoupling the CRAM array from the FPGA fabric is proposed by the examples. By isolating the configuration storage from the programmable logic and interconnects, this approach introduces new opportunities for reliability, repairability, and flexibility. In FIG. 1, the structure 100 includes two components, that is, the FPGA fabric chiplet 110 and the CRAM chiplet 150. The configuration storage is thus embedded in the CRAM chiplet 150 and the programmable logic and interconnects remain in the FPGA fabric chiplet 110. Additionally, the FPGA fabric chiplet 110 includes a backside power rail (BPR) 120 to enable communication between the FPGA fabric chiplet 110 and the CRAM chiplet 150.

The FPGA fabric chiplet 110 includes circuitry 112 and the CRAM chiplet 150 also includes circuitry 170. The microbumps 135 are used to connect or couple the BPR 120 of the FPGA fabric chiplet 110 to the CRAM chiplet 150.

In the FPGA fabric chiplet 110, the BPR 120 may include Q/QB signals, as well as the power and ground sources. For example, the BPR 120 shows Q nodes, such as Q0 node 122 and Q1 node 124. The BPR 120 also shows QB nodes, such as QB1 node 126 and QB2 node 128. The BPR 120 may include any number of Q/QB nodes. The BPR also includes power source (VDD) 130 and ground source (VSS) 132. VDD 130 refers to the positive voltage supply and VSS 132 refers to the ground or negative voltage supply. The VDD 130 and the VSS 132 may be embedded within the BPR 120.

The CRAM chiplet 150 may include Q/QB signals, as well as the power and ground sources. For example, Q nodes, such as Q1 node 152 and Q2 node 154 are shown. QB nodes, such as QB1 node 156 and QB2 node 158 are also shown. The CRAM chiplet 150 may include any number of Q/QB nodes. The CRAM chiplet 150 also includes power source (VDD) 160 and ground source (VSS) 162. VDD 160 refers to the positive voltage supply and VSS 162 refers to the ground or negative voltage supply. The VDD 160 and the VSS 162 are coupled to the respective VDD 130 and VSS 132 in the BPR 120 of the FPGA fabric chiplet 110.

BPR 120 moves power delivery networks (PDNs) to the backside of a chip, freeing up valuable routing resources on the front side (active surface). Traditionally, power and signal interconnects share the same front-side metal layers, leading to congestion and limitations in scaling. By relocating power rails to the backside, the BPR 120 improves power delivery efficiency, enhances chip performance, and allows for greater design flexibility. As such, the front side of the chip is reserved for signal routing and active circuit elements. This reduces routing congestion and allows for denser, higher-performance signal paths. The backside hosts the power and ground rails, providing a dedicated PDN that connects to the active layers through vias. The BPR 120 relies on back-side vias (BSVs) 123 & 127 and the back-side metal rails 125 to connect the transistors and circuits on the front side of the chip. These BSVs are engineered to minimize resistance and improve power delivery efficiency. Their extremely small pitch, usually below sub-100 nanometers, is comparable to transistor gate pitch. This allows dense signal connections required by CRAM Q/QB tapping into transistors. To accommodate the tight pitch and manufacturable aspect ratio for BSVs, the transistors substrate 121 must be heavily thinned down to within a few hundred nanometers or less through backside polishing. The BPR 120 integrates seamlessly with advanced packaging techniques such as chiplet designs, 2.5D/3D integration, and hybrid bonding. The BPR 120 facilitates modular architectures by enabling efficient power delivery to stacked or adjacent chiplets. Removing power rails from the front side provides more metal layers and routing space for signal interconnects, enabling denser and more complex designs. This is particularly beneficial for logic-dense chips like FPGAs, graphics processing units (GPUs), and artificial intelligence (AI) accelerators.

In the examples, the BPR 120 enables decoupling of configuration memory from the programmable logic fabric. The BPR 120 ensures efficient power delivery to both tiers or chiplets in a 3D or chiplet-based architecture. The BPR 120 supplies power and ground to both the FPGA fabric (including the CLEs and INT muxes) and the configuration memory (e.g., CRAM arrays) through back-side vias and microbumps in advanced packaging flows like SoIC or CoWoS. The FPGA fabric and configuration memory can be implemented in separate tiers or chiplets, with the BPR 120 providing a shared, efficient power delivery system across both components.

Therefore, separating the CRAM chiplet 150 from the FPGA fabric chiplet 110 offers several performance and scalability advantages. The example approach involves using the BPR 120 to provide power, ground, and signal connections between the CRAM chiplet 150 and the FPGA fabric chiplet 110, using fine metal and via pitch for high-density integration. This decoupling enables more flexible, scalable, and efficient FPGA designs, particularly in advanced packaging schemes like chiplets, 3D stacking, and hybrid bonding.

As such, the BPR technology moves the power and ground delivery system to the backside of the chip. This frees up valuable routing space on the front side, where signal interconnects between logic elements, programmable logic, and memory are arranged. Using the BPR 120 for interconnection between the CRAM chiplet 150 and the FPGA fabric chiplet 110 allows these components to be separated spatially, but still communicate efficiently through dedicated, high-density connections. The fine metal and via pitch of the BPR 120 are fundamental in this setup. Fine-pitch metal layers enable higher routing density, while small vias allow for efficient connections between the backside and front-side logic elements. These fine-grained connections ensure that the FPGA fabric chiplet 110 and the CRAM chiplet 150 can communicate with minimal signal loss or delay, even over relatively long distances in terms of chip architecture.

The CRAM chiplet 150 is responsible for storing and managing configuration data that programs the FPGA fabric chiplet 110. The CRAM chiplet 150 includes not just the CRAM array, which holds configuration data, but also additional circuitry for reading, writing, and potentially repairing the configuration memory. By decoupling the CRAM from the FPGA fabric and placing it in a separate chiplet, the design gains flexibility, modularity, and improved fault tolerance. Since the configuration memory is typically rewritten infrequently, placing it in a dedicated chiplet allows for better optimization of memory storage and management. Further, this modularity opens up possibilities for incorporating redundancy or using advanced memory types, such as DRAM or non-volatile memories, which are difficult to integrate within the dense FPGA fabric itself.

The FPGA fabric chiplet 110, which includes the programmable logic elements like the CLEs, INT muxes, and routing resources, is the heart of the FPGA. The muxes route signals between various logic blocks based on the configuration data stored in the CRAM chiplet 150. By separating the CRAM from the FPGA fabric, the FPGA fabric chiplet 110 can focus on optimizing the logic resources and interconnections while the CRAM chiplet 150 can handle the configuration storage independently. The FPGA fabric chiplet 110 handles complex signal routing tasks through its muxes, which are programmed to route data based on the configuration values they receive from the CRAM chiplet 150. This separation allows the FPGA fabric to remain more agile, as the configuration is updated independently, without impacting the logic resources themselves.

The fine-pitch metal and vias of the BPR 120 allow for efficient and high-speed communication between the CRAM chiplet 150 and the FPGA fabric chiplet 110. Through these interconnections, the Q/QB outputs from the CRAM chiplet 150 are sent to control the FPGA fabric's muxes. The power and ground are also shared across both chiplets via the BPR, ensuring a consistent and efficient power delivery system. By placing power delivery on the backside, the interconnect between the CRAM chiplet 150 and the FPGA fabric chiplet 110 is less susceptible to noise and interference, which can impact the performance of high-frequency logic circuits. The back-side interconnects can thus achieve higher performance and reliability than traditional front-side connections.

The separation of the CRAM chiplet 150 from the FPGA fabric chiplet 110 allows for greater flexibility in the design and configuration of both components. For example, the CRAM chiplet 150 can be replaced or upgraded without impacting the FPGA fabric, and additional CRAM chiplets can be added to support more extensive configuration storage if needed. Additionally, the chiplet-based design makes it easier to integrate different types of memory within the CRAM chiplet 150. For example, the CRAM chiplet 150 may include not only SRAM for configuration storage but also DRAM for more expansive memory needs, providing a hybrid memory solution. This would be difficult to achieve in traditional FPGA designs, where memory and logic are integrated into the same chip.

Therefore, decoupling the CRAM from the FPGA fabric and using backside power rail technology results in a highly efficient, flexible, and scalable FPGA architecture. By utilizing fine-grained metal and via connections, this approach minimizes signal delay and maximizes communication efficiency between the configuration memory and the FPGA fabric. Further, it allows for greater modularity and fault tolerance, making it easier to upgrade, repair, or expand FPGA systems.

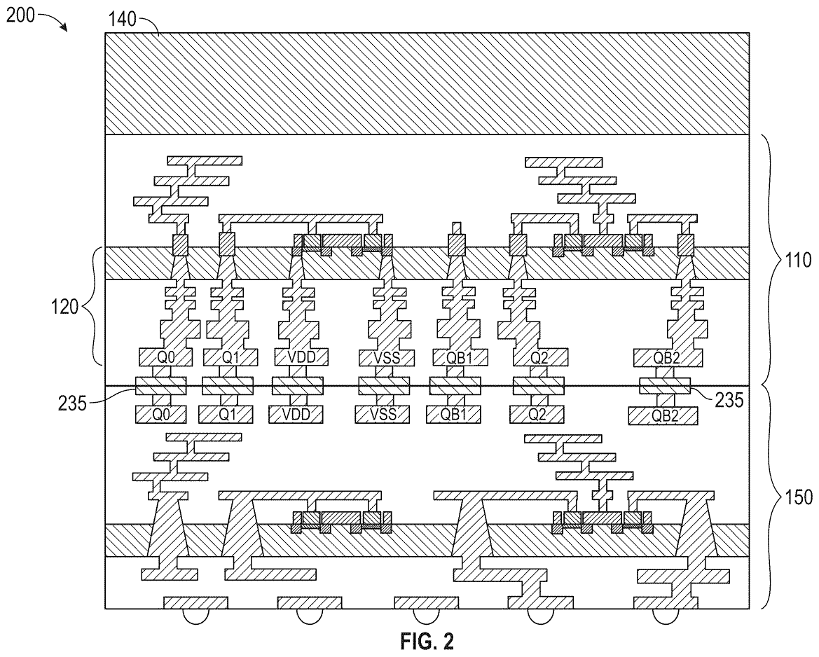

FIG. 2 illustrates a cross-sectional view of a FPGA fabric chiplet including a BPR and a CRAM chiplet connected to the FPGA fabric chiplet with BPR using hybrid bonding, according to an example.

FIG. 2 is similar to FIG. 1 and, as such, a description of similar elements will be omitted for clarity and conciseness. The difference between FIGS. 1 and 2 is the connection between the FPGA fabric chiplet 110 and the CRAM chiplet 150. Instead of using the microbumps 135, the structure 200 uses hybrid bonding 235. As such, the difference is the junction between the FPGA fabric chiplet 110 and the CRAM chiplet 150. The structure 200 may be referred to as system-on-integrated-chip (SoIC) structure. The structure 200 may be referred to as a chip package or semiconductor package assembly or semiconductor chip device.

Hybrid bonding 235 may involve oxide and metal bonding. That is, a layer of dielectric oxide may be deposited on the bonding surfaces of both the FPGA fabric chiplet 110 and the CRAM chiplet 150. When the two surfaces are brought together, the oxides bond through van der Waals forces. Electrical connections between top and bottom dies are made by bonding pre-deposited and patterned metal pads. Copper is a common metal to use in hybrid bonding. Post bond annealing enhances the bond by forming covalent bonds at the oxide interface.

The FPGA fabric chiplet 110 is bonded to the CRAM chiplet 150 such that the Q/QB nodes of the FPGA fabric chiplet 110 match or line up with the Q/QB nodes of the CRAM chiplet 150. Additionally, the VSS and VDD connections of the FPGA fabric chiplet 110 match or line up with the VSS and VDD connections of the CRAM chiplet 150.

Decoupling the CRAM array from the FPGA fabric can also be achieved through the semiconductor-on-insulator chip (SoIC) flow, an advanced 3D integration technology that enables the stacking of heterogeneous tiers with high-density interconnects. In this architecture, the FPGA fabric and CRAM array are placed into separate tiers. The FPGA fabric tier includes the CLEs and INT multiplexers, while the CRAM tier houses the configuration memory array and associated circuitry for reading, writing, and repair. Hybrid bonding technology establishes direct connections between the fabric tier's backside and the CRAM tier's front side, ensuring seamless communication and power delivery between the tiers.

The FPGA fabric tier focuses entirely on programmable logic and routing resources, free from the integration constraints of embedded CRAM. The absence of embedded CRAM bit cells allows for an optimized layout, improving the density and performance of CLEs and INT muxes. Further, the separation enables the FPGA fabric to be fabricated using a process technology tailored for high-speed logic and routing. This enhances the electrical performance and reduces the power consumption of the programmable fabric, particularly for advanced FPGAs targeting demanding applications like AI and high-performance computing.

The CRAM array tier is designed specifically for configuration memory and associated support circuits. The CRAM array includes the CRAM bit cells, read/write logic, and redundancy features such as spare rows and columns for repair. By isolating CRAM into its own tier, the memory can be fabricated using a technology optimized for density and reliability, such as an SRAM process or a DRAM process. This decoupling also simplifies the implementation of error correction and redundancy mechanisms, which are valuable for ensuring data integrity and maintaining high yields in advanced process nodes.

Hybrid bonding integrates the FPGA fabric and CRAM array tiers in the SoIC flow. This process involves creating a direct bond between the backside of the fabric tier and the front side of the CRAM tier, providing high-density interconnects with minimal resistance and parasitics. Through these hybrid bonds 235, the Q/QB signals from the CRAM array are routed directly to the INT muxes and CLEs on the FPGA fabric tier. The hybrid bonding also enables power and ground delivery across the tiers, eliminating the need for external power distribution layers and enhancing power integrity.

The SoIC-based decoupling approach offers significant benefits over traditional monolithic FPGA designs. By separating the CRAM array and FPGA fabric into different tiers, each tier can be optimized independently, leading to better performance and area efficiency. Hybrid bonding ensures that the communication between tiers remains fast and reliable, preserving the overall FPGA performance. Additionally, the modularity of the design allows for easier repair and scalability, that is, defective CRAM tiers can be replaced without affecting the FPGA fabric, and the tiers can be scaled independently to accommodate larger designs or more complex configurations.

The examples improve the repairability and functionality of FPGA designs while decoupling the CRAM from the FPGA fabric by utilizing a BPR to connect the CRAM's Q/QB signals to the FPGA fabric's INT muxes and CLEs through small, efficient vias. In this approach, the Q/QB output signals from the CRAM chiplet are routed via the BPR, which has a via pitch small enough to feed directly into the compact circuits of the FPGA fabric without introducing significant area overhead or design complexity. The BPR provides an efficient, high-density routing solution for the Q/QB signals from the CRAM chiplet to the FPGA fabric chiplet, allowing the signals to be delivered directly to the INT muxes and CLEs. The small via pitch in the BPR ensures that the routing of these signals can occur with minimal impact on the overall area of the FPGA fabric. This is beneficial in maintaining the tight density requirements for FPGA designs, which often involve compact, highly efficient circuit layouts. By using this approach, designers can achieve seamless communication between the CRAM and the fabric without needing to expand the chip's footprint. Additionally, the integration of the FPGA fabric chiplet with the CRAM chiplet is facilitated through advanced packaging techniques such as SoIC or CoWoS hybrid bonding. In these configurations, the FPGA fabric chiplet is electrically connected to the CRAM chiplet using microbumps on an interposer, ensuring that the electrical connections between the two chiplets are both robust and efficient.

The examples above describe decoupling FPGA fabric from CRAM memory. Configuration memory in an FPGA is a specialized storage resource that holds the data defining the device's programmable logic and routing. Configuration memory serves as the backbone of the FPGA's reconfigurable architecture, enabling users to program and reprogram the device to perform specific tasks. The stored data in the configuration memory defines the behavior of programmable components such as LUTs, multiplexers (muxes), and routing paths. Configuration memory is typically implemented using SRAM cells, although alternative technologies such as Flash are also used in certain FPGA families. SRAM-based configuration memory is widely preferred due to its high density, fast access times, and ability to be rewritten easily, making it suitable for applications requiring flexibility and reprogramming. However, because SRAM is volatile, it needs an external or embedded configuration mechanism to reload the configuration data after power-up.

Therefore, the examples are not limited to only CRAM memory. When decoupling the FPGA from memory, it is not limited to the CRAM memory but can extend to other types of memory systems. In other words, once the CRAM is moved out of the FPGA fabric, other memories alone or in combination with CRAM may be employed. Such memories may include SRAM, DRAM, flash memory, high bandwidth memory (HBM), non-volatile memory (NVM), hybrid memory, registers and cache memory. SRAM is a high-speed, low-latency memory type used for cache, buffering, or small data storage in many systems. SRAM is volatile, meaning it loses its content when power is turned off. DRAM is a more common memory type used for larger storage capacities, though it has slower access speeds than SRAM. Flash memory is non-volatile memory commonly used for data storage. NAND Flash is used for high-capacity storage, while NOR Flash offers faster read speeds and is often used for code storage. HBM is a high-performance memory technology that offers extremely high bandwidth, allowing for rapid data transfer between memory and processing units. Non-volatile memory (NVM) includes magnetoresistive RAM (MRAM), phase change memory (PCM), and resistive RAM (ReRAM), which combine the speed of DRAM with non-volatility.

Decoupling the FPGA from its memory enables much greater flexibility and scalability by allowing the use of a wide range of memory types based on the specific needs of the system. Whether it is the high-speed performance of SRAM and HBM, the persistent nature of Flash and NVM, or the high-capacity nature of DRAM, each memory type brings unique benefits to FPGA-based systems. By integrating these memory systems with the FPGA, one can tailor the system for optimal performance, cost, and power efficiency, making it well-suited for a wide variety of applications such as AI, machine learning, real-time processing, and cloud computing.

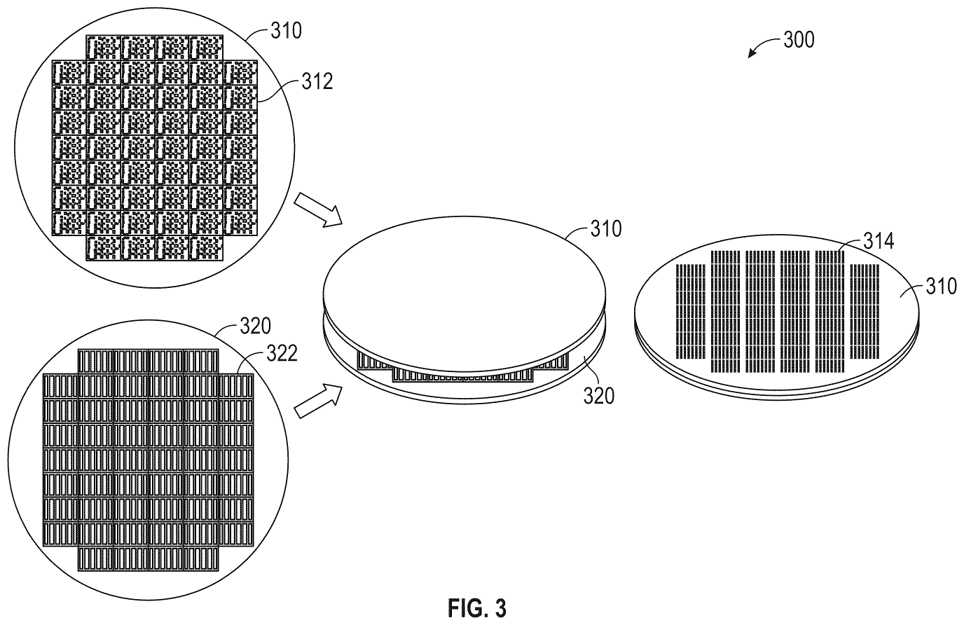

FIG. 3 illustrates a process for bonding a first wafer including FPGA fabric chiplets to a second wafer including CRAM chiplets, according to an example.

In FIG. 3, a first wafer 310 includes the FPGA fabric chiplets 312 and the second wafer 320 includes the CRAM chiplets 322. As noted above, the chiplets in the second wafer 320 can be any type of memory chiplets, not limited to CRAM. The first wafer 310 is bonded with the second wafer 320 such that the BPR 120 of the FPGA fabric chiplets 312 directly contact the top surface of the second wafer 320. The bonding of the first wafer 310 (FPGA wafer) to the second wafer 320 (CRAM wafer) establishes a connection between the FPGA fabric and the CRAM memory systems. This approach enables the integration of the BPR 120 with Q/QB signals and VSS/VDD between the two wafers, using, e.g., hybrid bonding techniques. The BPR 120 ensures that VDD and VSS power rails, as well as Q/QB signals can interface with the second wafer. The Q/QB signals representing the output of the CRAM cells are routed through back-side vias (BSVs) in the FPGA wafer's BPR to directly feed the FPGA's INT muxes and CLEs. The FPGA fabric and the CRAM arrays share common VDD and VSS to ensure consistent and reliable power delivery across both wafers. By using the BPR and fine-pitch vias, the physical integration of the two wafers is achieved without significant area overhead.

After bonding, the TSVs 314 of the first wafer 310 can be exposed. The TSVs 314 are exposed to enable external connectivity and ensure efficient integration of the bonded stack into the larger system or package. The TSVs 314 of the first wafer 310 serve as vertical electrical interconnects that pass signals and power through the Si substrate. Exposing the TSVs 314 allows for signal routing, power delivery, and programming interfaces. For example, in a CoWoS, the TSVs 314 may connect to interposers. In other configurations, the TSVs 314 may connect to solder bumps for flip-chip mounting onto a printed circuit board (PCB).

There are several benefits in decoupling the CRAM from the FPGA fabric.

Decoupling the CRAM from the FPGA fabric removes the constraints imposed by the need to tightly integrate the CRAM with the programmable logic resources. In traditional FPGA designs, the CRAM array is placed adjacent to the INT muxes and CLEs, which involves careful layout planning and limiting design flexibility. By separating these two components into distinct chiplets, the FPGA fabric is no longer constrained by the need for CRAM and INT/CLE rows to be in close proximity. This separation allows for more efficient utilization of the fabric's logic resources and greater flexibility in optimizing the layout of the logic and interconnects, leading to improved overall performance and design scalability.

When CRAM is placed as a separate chip, it opens up opportunities for more advanced and independent memory repair schemes. In traditional FPGA designs, repairing faulty configuration memory involves complex workarounds within the fabric. However, with the CRAM in its own chiplet, it becomes easier to implement redundancy and repair mechanisms specifically tailored for the CRAM array, such as ECC, spare memory cells, or even dynamic reconfiguration capabilities. This approach allows for a more robust and fault-tolerant memory subsystem, improving the overall reliability and longevity of the FPGA.

Yield failure in FPGAs arises from defects or faults within the CRAM cells, which program the FPGA fabric. In traditional FPGA designs, any issues with the CRAM can cause yield losses because the CRAM cells are closely coupled with the logic elements. By decoupling the CRAM from the FPGA fabric and placing it in a separate chiplet, the impact of such failures can be greatly reduced. If defects are found in the CRAM, they can be isolated, and the memory repair scheme implemented within the CRAM chiplet can mitigate their effects. Further, with a separate CRAM chip, defective memory cells can be bypassed or reprogrammed independently, reducing the overall impact on FPGA yield. This enhances manufacturing yield and reduces the likelihood of having defective or underperforming FPGAs.

With the CRAM placed in a separate chiplet, the configuration memory can be upgraded, replaced, or repaired without affecting the FPGA fabric itself. This decoupling allows for a more modular design, where different types of configuration memory (e.g., SRAM, DRAM, non-volatile memory) can be chosen based on specific performance and application requirements. The ability to upgrade or change the CRAM chip also enables faster adoption of newer memory technologies without the need for a complete redesign of the FPGA fabric. This flexibility allows for future-proofing of FPGA designs.

The separation of CRAM and FPGA fabric into distinct chiplets not only improves performance but also enhances reliability by isolating faults. In a traditional FPGA, a failure in the configuration memory impacts the entire system. However, in a chiplet-based approach, faults in the CRAM can be detected and managed separately, improving the overall robustness of the FPGA. This isolation of failure modes ensures that issues with configuration memory do not propagate to the logic or interconnect layers, enhancing the resilience of the entire system. Moreover, fault isolation simplifies debugging and testing, as defects can be pinpointed to the memory layer, streamlining repair and maintenance.

Decoupling the FPGA fabric from the CRAM read-write functionality presents a significant benefit in enabling real-time reconfiguration or correction of FPGA functionality. Traditionally, the configuration memory is coupled with the FPGA logic, meaning that any modification or correction to the FPGA's functionality involves reprogramming the entire configuration memory, which can be time-consuming and disruptive. By isolating the CRAM, it becomes possible to make changes or corrections to the FPGA's configuration dynamically without interrupting its ongoing operations.

The decoupling of CRAM from the FPGA fabric allows for the configuration memory to be independently accessed, modified, or repaired. In the case of errors or failures in the configuration memory, such as single-bit failures, these issues can be addressed in real-time, ensuring that the FPGA can continue to operate without needing a full reset or reprogramming cycle. This capability is valuable in mission-critical applications where uptime and continuous operation are paramount.

Further, with real-time reconfiguration, the FPGA can adapt to changing conditions, such as different workloads or environmental factors, without the need for significant downtime. For instance, if an FPGA is used in a dynamic system where performance requirements evolve over time, it can be reprogrammed on the fly to optimize its configuration for new tasks or improve efficiency. This real-time adaptability ensures that the FPGA remains efficient and responsive to the needs of the system, providing a higher degree of flexibility compared to traditional, static FPGAs.

Additionally, this real-time reconfiguration or correction capability facilitates the use of advanced repair mechanisms, such as ECC, to detect and correct faults in the CRAM. When a bit failure occurs in the configuration memory, the system can apply the necessary corrections without stopping the operation of the FPGA. This reduces the risk of system downtime due to memory-related issues, improving overall system reliability and yield.

Ultimately, the ability to decouple the CRAM from the FPGA fabric opens up new possibilities for on-the-fly adjustments, enabling more flexible, efficient, and resilient FPGA designs that are capable of real-time correction and reconfiguration to meet the evolving needs of the application.

Moreover, by decoupling the CRAM from the FPGA fabric and using a backside power rail, FPGA architectures can achieve a more modular and secure configuration system. This separation allows all device protection mechanisms to be readily updated in the future by isolating them in the configuration die, ensuring future-proof security enhancements.

For example, if new security methodologies are introduced, only the configuration layer (CRAM) needs to be updated, rather than requiring modifications to the entire FPGA layer. Traditional FPGA architectures, where CRAM is embedded within the same silicon as the logic fabric, face challenges when evolving security threats demand patches, updates, or entirely new protection mechanisms. With a separate configuration layer, FPGA security can be dynamically improved without costly and complex changes to the main FPGA fabric.

This approach enhances hardware security and resilience against attacks such as side-channel attacks, tampering, and unauthorized bitstream modifications. The backside power rail further reinforces security by isolating the CRAM's power delivery, making it more difficult for adversaries to interfere with or extract sensitive information through power analysis techniques. Since the CRAM is physically and electrically separated, fault injection attacks and voltage manipulation attempts become considerably harder to execute.

Additionally, this modular security architecture simplifies compliance with evolving industry security standards. Many FPGA-based systems operate in industries where security certifications require periodic updates. By decoupling security mechanisms into an upgradable CRAM layer, FPGA vendors and users can integrate new encryption methods, authentication protocols, or cryptographic techniques as they emerge, without redesigning the entire FPGA fabric.

Further, with growing concerns about manufacturing processes, a decoupled CRAM architecture allows security-critical features to be developed and updated independently from the main FPGA manufacturing process. This separation makes it feasible for FPGA vendors to retain control over security-sensitive components, reducing the risk of tampering during fabrication, packaging, or distribution.

As such, decoupling CRAM from the FPGA fabric using a backside power rail provides a highly secure, flexible, and future-proof solution. This architecture enables rapid security updates and supports new cryptographic methodologies without the need for modifications to the core FPGA logic. If new security methodologies emerge, only the configuration layer needs to be upgraded.

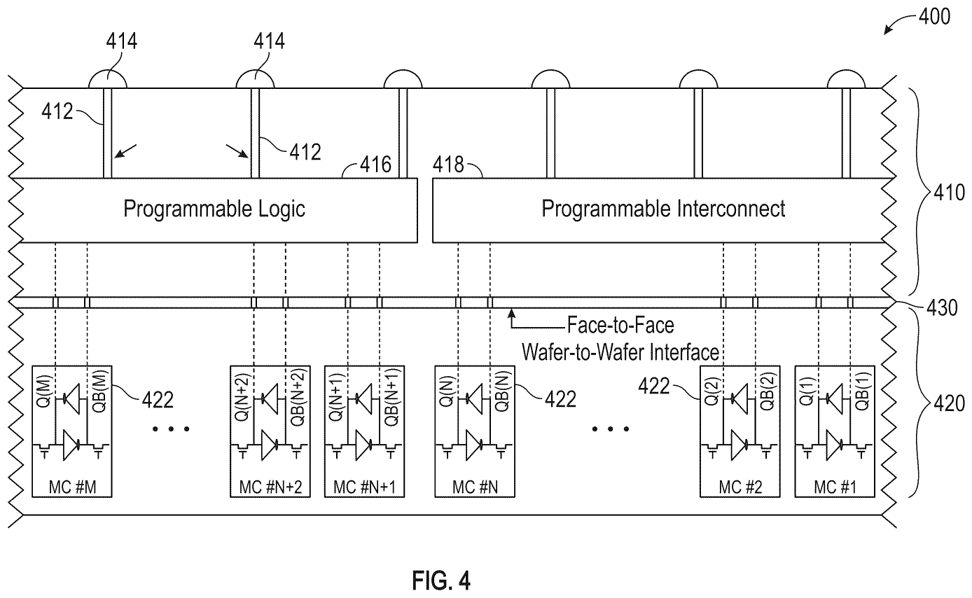

FIG. 4 illustrates a face-to-face wafer-to-wafer interface, according to an example.

In another example, structure 400 shows a face-to-face wafer-to-wafer interface 430 connecting FPGA fabric 410 to CRAM 420. The FPGA fabric 410 includes TSVs 412 connected to microbumps 414, as well as programmable logic 416 and programmable interconnects 418. The CRAM 420 includes multiple CRAM cells 422. Instead of using a BPR, the FPGA fabric 410 is connected or coupled to CRAM 420 via a face-to-face interface.

Using a face-to-face wafer-to-wafer (W2W) interface instead of a back-side power rail (BPR) for connecting the FPGA fabric to CRAM offers an alternative approach to integrating these two components. This approach relies on directly bonding the top surfaces of the FPGA and CRAM wafers, creating a dense, high-performance interconnection layer for signal and power delivery.

In face-to-face wafer bonding, the front sides of the two wafers (FPGA fabric wafer and CRAM memory wafer) are aligned and bonded together. The front side of each wafer includes the active circuitry, including the metal interconnect layers and pads for connections. This method eliminates the need to expose TSVs or rely on back-side vias, as all connections occur directly through the bonded interface. The Q/QB output signals from the CRAM memory cells are routed through fine-pitch bonding pads on the CRAM wafer to corresponding bonding pads on the FPGA wafer, establishing direct electrical connections. Shared power and ground rails are routed through the face-to-face bonding interface. This ensures that both wafers receive a stable power supply without relying on a separate back-side power structure.

The face-to-face interface allows for fine-pitch bonding (e.g., pitches as small as a few microns), supporting thousands to millions of interconnects. This is beneficial for Q/QB signals, which use a high-density interface to drive the FPGA's fine-grained INT and CLEs.

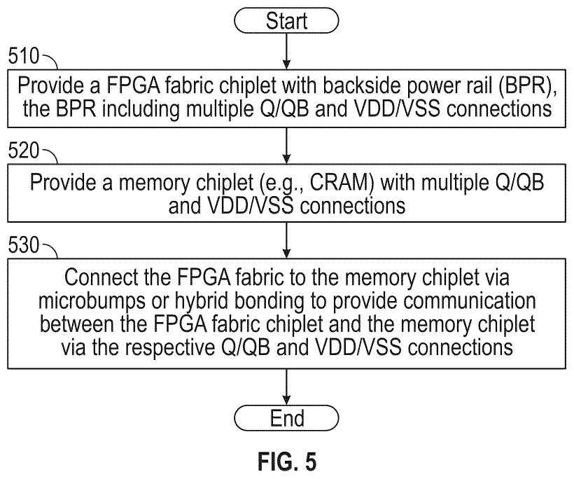

FIG. 5 illustrates a method for decoupling the FPGA fabric chiplet with BPR from the CRAM chiplet, according to an example.

At 510, a FPGA fabric chiplet with backside power rail (BPR) is provided, the BPR including multiple Q/QB and VDD/VSS connections. The BPR process removes power delivery from the active signal-routing layers, significantly reducing congestion and improving signal integrity. The FPGA fabric chiplet includes the core programmable elements, such as CLEs for logic implementation and INT muxes for routing signals across the fabric.

At 520, a memory chiplet (e.g., CRAM) is provided with multiple Q/QB and VDD/VSS connections. The CRAM chiplet is dedicated to configuration storage and management. The CRAM chiplet houses the CRAM array, read/write circuitry, redundancy mechanisms for repair, and any other circuits necessary for error detection and correction.

At 530, the FPGA fabric chiplet is connected to the memory chiplet via microbumps or hybrid bonding to provide communication between the FPGA fabric chiplet and the memory chiplet via the respective Q/QB and VDD/VSS connections.

In conclusion, decoupling CRAM from the FPGA fabric offers improved reliability, scalability, and functionality. By relocating configuration memory to dedicated blocks that are physically separated from the fabric, designers can integrate more robust and repairable memory technologies, such as SRAM macros with redundancy, DRAM, register files, or flip-flops. These technologies provide enhanced error tolerance and repairability, ensuring higher yields and greater resistance to soft errors, particularly in advanced process nodes where defect rates and radiation susceptibility pose challenges.

The integration of back-side power technology further amplifies the advantages of decoupling CRAM. By separating power delivery from the signal and configuration planes, back-side power minimizes interference and congestion in the FPGA's active layers. This approach enables efficient routing of configuration signals while simultaneously improving power integrity and thermal management. Additionally, the space savings in the active layer can be leveraged to accommodate new functionality, such as expanded logic resources, enhanced interconnects, or even embedded accelerators, further broadening the FPGA's versatility.

Decoupled CRAM combined with back-side power enables dynamic reconfiguration capabilities, supports larger and more complex designs, and facilitates the adoption of emerging memory technologies. Together, these advancements position FPGAs as even more powerful and flexible tools for modern applications, ranging from AI and machine learning to high-performance computing and networking.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. A chip package comprising:
a field-programmable gate array (FPGA) fabric chiplet including a backside power rail (BPR), wherein the FPGA fabric chiplet excludes memory elements; and
a memory chiplet electrically connected to the FPGA fabric chiplet.

2. The chip package of claim 1, wherein the memory chiplet is a configurable random access memory (CRAM).

3. The chip package of claim 1, wherein the FPGA fabric chiplet includes programmable interconnects (INT) and configurable logic elements (CLEs) and the memory chiplet includes memory elements and associated circuitry.

4. The chip package of claim 1, wherein the FPGA fabric chiplet is electrically connected to the memory chiplet using hybrid bonding.

5. The chip package of claim 1, wherein the FPGA fabric chiplet is electrically connected to the memory chiplet using microbumps.

6. The chip package of claim 1, wherein the BPR of the FPGA fabric chiplet includes logic state (Q/QB) nodes, a positive supply voltage, and a negative supply voltage.

7. The chip package of claim 6, wherein the memory chiplet includes Q/QB nodes, a positive supply voltage, and a negative supply voltage.

8. The chip package of claim 7, wherein Q/QB signals from the memory chiplet traverse through back-side vias (BSVs) of the BPR to microbumps, where they are routed to corresponding INT and CLEs in the FPGA fabric chiplet.

9. A chip package comprising:
a memory array including configuration memory and associated support circuits for reading, writing, and repair; and
a field-programmable gate array (FPGA) fabric including configurable logic elements (CLEs) and interconnect (INT) multiplexers, wherein the FPGA fabric is stacked onto the memory array.

10. The chip package of claim 9, wherein the FPGA fabric includes a backside power rail (BPR).

11. The chip package of claim 10, wherein the BPR is configured to supply power and ground to both the memory array and the FPGA fabric using back-side vias (BSVs) and back-side metal rails.

12. The chip package of claim 10, wherein the BPR is configured to supply logic states (Q/QB) to both the memory array and the FPGA fabric using BSVs.

13. The chip package of claim 9, wherein electrical connection between the memory array and the FPGA fabric is established using hybrid bonding.

14. The chip package of claim 9, wherein Q/QB signals from the memory array are routed directly to the INT multiplexers and CLEs on the FPGA fabric.

15. The chip package of claim 9, wherein the FPGA fabric excludes memory elements.

16. A method comprising:
forming a backside power rail (BPR) in a field-programmable gate array (FPGA) fabric chiplet excluding memory elements; and
electrically connecting a memory chiplet to the FPGA fabric chiplet.

17. The method of claim 16, wherein the memory chiplet is a configurable random access memory (CRAM).

18. The method of claim 16, wherein the FPGA fabric chiplet includes programmable interconnects (INT) and configurable logic elements (CLEs) and the memory chiplet includes memory elements and associated support circuits for reading, writing, and repair.

19. The method of claim 16, wherein the BPR is configured to supply power, ground, and logic states (Q/QB) to both the memory chiplet and the FPGA fabric chiplet using BSVs.

20. The method of claim 16, wherein the FPGA fabric chiplet is electrically connected to the memory chiplet using hybrid bonding such that Q/QB signals from the memory chiplet are routed directly to INT multiplexers and CLEs on the FPGA fabric chiplet.
